(19) United States
(12) Patent Application Publication
(10) Pub. No.: US 2020/0235822 A1
(43) Pub. Date: Jul. 23, 2020

(54) BURST LIGHT RECEIVER

(71) Applicant: Mitsubishi Electric Corporation, Tokyo (JP)

(72) Inventors: Satoshi YOSHIMA, Tokyo (JP); Daisuke MITA, Tokyo (JP)

(73) Assignee: Mitsubishi Electric Corporation, Tokyo (JP)

(21) Appl. No.: 16/088,590

(22) PCT Filed: May 25, 2016
(86) PCT No.: PCT/JP2016/065432

§ 371 Date: Sep. 26, 2018

(51) Int. Cl. H04B 10/69; H04B 10/67; H01L 31/02; H01L 31/107

(52) U.S. Cl. CPC H04B 10/69; H01L 31/107; H01L 31/02027; H04B 10/67

(57) ABSTRACT

A burst light receiver includes a booster circuit that generates a voltage applied to an avalanche photodiode, a first path in which a resistor to step down the voltage generated by the booster circuit is inserted, a second path provided in parallel to the first path, a switch circuit that is provided between the booster circuit and the first and second paths to select the first path or the second path, a current detecting circuit that controls the switch circuit in such a manner that the booster circuit is connected to the first path when a value of a current flowing from the booster circuit to the avalanche photodiode becomes equal to or larger than a first threshold, and the booster circuit is connected to the second path when the value of the current becomes smaller than a second threshold.

### FIELD

The present invention relates to a burst light receiver applied to an optical communication system.

### BACKGROUND

A one-to-many optical communication system employing a time-division multiplexing system has a configuration in which a plurality of slave-station devices are connected to one master-station device. Opportunities of transmission are assigned to the slave-station devices in a time-division manner. Optical signals received by the master-station device in the uplink from the slave-station devices to the master-station device are burst signals that are different in receiving power among the slave-station devices because of differences in distances to the respective slave-station devices, for example. Therefore, a receiver of the master-station device is required to have a wide dynamic range. In a one-to-many optical communication system, power of a light transmitter and sensitivity of a light receiver in a master-station device are improved for increasing the number of branches and elongating the transmission distance, and an avalanche photodiode (APD) that uses an avalanche effect is used as a light-receiving element in many cases.

In an APD, a current multiplication factor in accordance with a voltage applied to the APD is usually set to 1 or more for achieving high sensitivity. As a result, it is likely that a waveform distortion is generated to cause a bit error in a case where high-power light is input. In some cases, the APD brakes down. In order to avoid this problem, there have conventionally been taken measures that a voltage applied to an APD is stepped down when high-power light is input (Patent Literature 1), and a current path to an APD is changed (Patent Literature 2).

### CITATION LIST

### Patent Literatures

Patent Literature 1: Japanese Patent Application Laid-open No. 2007-129639

Patent Literature 2: Japanese Patent Application Laid-open No. 2008-028537

### SUMMARY

### Technical Problem

The invention described in Patent Literature 1 employs a configuration in which a level of optical input power is determined based on an output of a preamplifier. Therefore, in a case of an excessive optical input, that is, a case where light of excessively high power is input, delay from detection of the excessive optical input until an APD driving circuit actually operates is large when delay in the preamplifier is considered. That is, a time required for stepping down a voltage applied to an APD is long, so that a possibility of increase of a bit error rate and a possibility of breakdown of the APD adversely become high.

A decoupling capacitor is generally inserted at the nearest position to an APD. In this case, when a value of resistance that is applied to the APD in series thereto from a constant voltage source is increased in order to protect the APD, a burst response is delayed by the decoupling capacitor, and therefore a large-value resistor cannot be mounted. As a result, the amount of drop of the voltage applied to the APD is limited to several volts. That is, in a case where a large-value resistor cannot be mounted, it is necessary to cause a current of tens of milliamperes to flow through a current path in order to produce voltage drop of tens of volts for protecting the APD in a case of an excessive optical input. However, the output current of the constant voltage source that generates the voltage applied to the APD is normally limited to several milliamperes. Therefore, it is not possible to protect the APD in a case of an excessive optical input.

Further, also in the invention described in Patent Literature 2, an upper limit value of resistance applied to an APD in series thereto from a constant voltage source is restricted from a viewpoint of a burst response speed, as in the invention described in Patent Literature 1. Therefore, a large-value resistor cannot be mounted. Accordingly, there is an identical problem to that of the invention described in Patent Literature 1, that is, the above-described problem that the APD cannot be protected in a case of an excessive optical input.

The present invention has been achieved in view of the above problems, and an object of the present invention is to provide a burst light receiver with improved performance of protecting an avalanche photodiode.

### Solution to Problem

To solve the above problems and achieve the object a burst light receiver according to the present invention includes: a booster circuit to generate a voltage applied to an avalanche photodiode; a first path provided between the booster circuit and the avalanche photodiode, in which a resistor to step down the voltage generated by the booster circuit is inserted; a second path provided in parallel to the first path; a switch circuit provided between the booster circuit and the first and second paths, to connect the booster circuit to the first path or the second path; and a path selecting unit to control the switch circuit in such a manner that the booster circuit is connected to the first path when a value of a current flowing from the booster circuit to the avalanche photodiode becomes equal to or larger than a first threshold, and the booster circuit is connected to the second path when the value of the current becomes smaller than a second threshold.

### Advantageous Effects of Invention

The burst light receiver according to the present invention has an effect where it is possible to improve performance of protecting an avalanche photodiode.

### BRIEF DESCRIPTION OF DRAWINGS

FIG. 1 is a diagram illustrating a configuration example of a burst light receiver according to a first embodiment.

FIG. 2 is a diagram illustrating an example of a detailed circuit configuration of the burst light receiver according to the first embodiment.

FIG. 3 is a diagram illustrating an operation example of a hysteresis comparator in a case where a level of an optical input to an APD is changed from a normal level to an abnormal level.

FIG. 4 is a diagram illustrating an operation example of the hysteresis comparator in a case where a level of an optical input to the APD is changed from an abnormal level to a normal level.

FIG. 5 is a diagram illustrating a configuration example of a burst light receiver according to a second embodiment.

### DESCRIPTION OF EMBODIMENTS

A burst light receiver according to embodiments of the present invention will be described in detail below with reference to the accompanying drawings. The present invention is not limited to the embodiments.

### First Embodiment

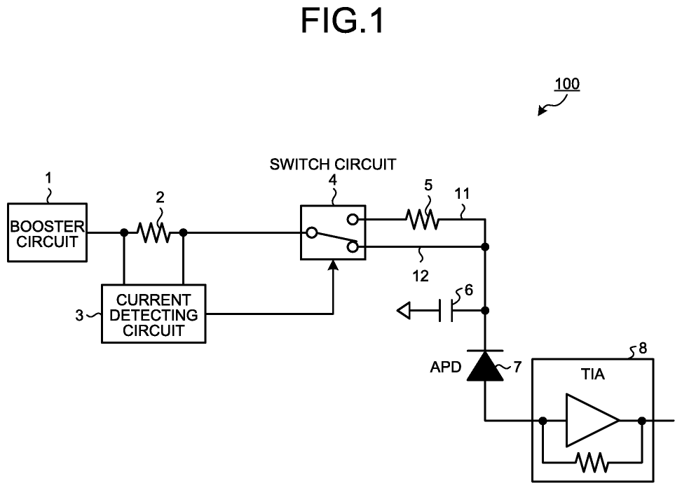

FIG. 1 is a diagram illustrating a configuration example of a burst light receiver according to a first embodiment of the present invention. A burst light receiver 100 according to the first embodiment includes a booster circuit 1, a resistor 2, a current detecting circuit 3, a switch circuit 4, a high resistor 5, a decoupling capacitor 6, an avalanche photodiode (APD) 7, and a transimpedance amplifier (TIA) circuit 8.

The booster circuit 1 generates a voltage applied to the APD 7. The resistor 2 is a current detecting resistor for detecting a current flowing from the booster circuit 1 to the APD 7. The current detecting circuit 3 detects a current flowing through the resistor 2 and controls the switch circuit 4 based on the detected current.

The switch circuit 4 is provided for switching the path of the current flowing from the booster circuit 1 to the APD 7, and selects either one of a first path 11 in which the high resistor 5 is inserted and a second path 12 in which the high resistor 5 is not inserted as the path of the current flowing from the booster circuit 1 to the APD 7. In a case where the first path 11 is selected by the switch circuit 4, the high resistor 5 lowers the voltage from the booster circuit 1 and applies the lowered voltage to the APD 7. That is, the high resistor 5 is a resistor for stepping down the voltage to be applied to the APD 7 from the booster circuit 1. The current detecting circuit 3 is a path selecting unit that controls the switch circuit 4 based on the value of the current flowing through the resistor 2 and that selects the path of the current flowing from the booster circuit 1 to the APD 7. The decoupling capacitor 6 removes noise to be input to the APD 7. The APD 7 converts an optical signal incident thereon to a current that corresponds to: a current multiplication factor, which is determined by the voltage applied from the booster circuit 1; and intensity of the incident optical signal, and outputs the resultant current to the TIA circuit 8. The TIA circuit 8 converts the current output from the APD 7 to a voltage signal.

In the burst light receiver 100 having the above configuration, the booster circuit 1 generates a voltage that sets the current multiplication factor of the APD 7 to 1 or more for achieving high sensitivity.

Although details will be described later, the current detecting circuit 3 in the burst light receiver 100 controls the switch circuit 4 in such a manner that the high resistor 5 is included in a current path from the booster circuit 1 to the APD 7 when the current flowing from the booster circuit 1 to the APD 7 has a value equal to or larger than a predetermined value.

Although the second path 12 out of the two paths switched by the switch circuit 4 is described as not including a circuit element that steps down the voltage to be applied to the APD 7, a configuration may be employed in which another resistor with a lower resistance value than that of the high resistor 5 is inserted in the second path 12. Further, although the decoupling capacitor 6 is arranged at the nearest position to the APD 7 in FIG. 1, a configuration can be employed in which a resistor is inserted before the APD 7, that is, a resistor is inserted between the decoupling capacitor 6 and the APD 7. The number of decoupling capacitors is not necessarily limited to one. Decoupling capacitors may be inserted at a plurality of positions, respectively.

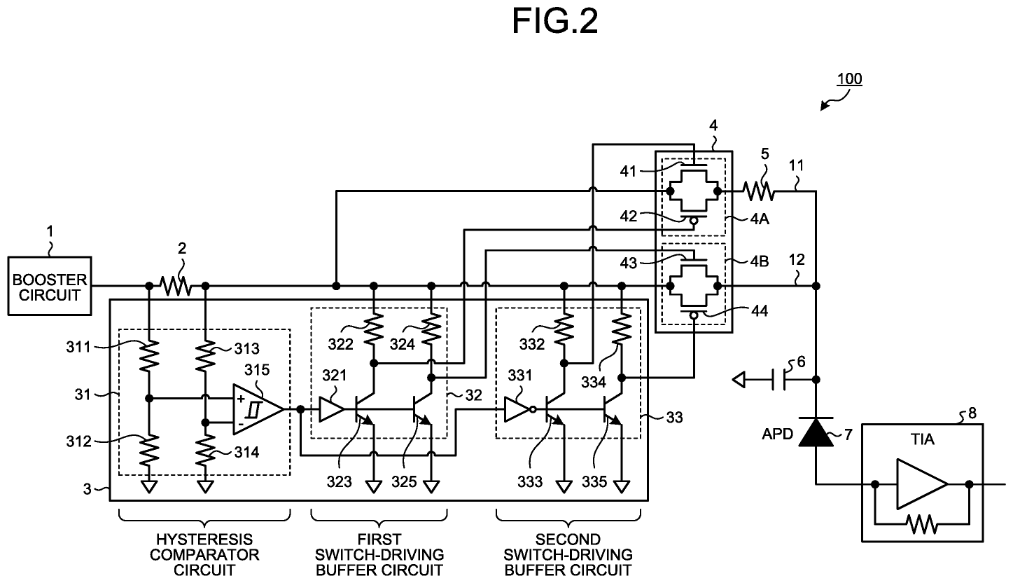

FIG. 2 is a diagram illustrating an example of a detailed circuit configuration of the burst light receiver according to the first embodiment, and illustrates a specific example of a circuit that achieves the current detecting circuit 3 and the switch circuit 4 illustrated in FIG. 1.

As illustrated in FIG. 2, the current detecting circuit 3 of the burst light receiver 100 includes: a hysteresis comparator circuit 31; a first switch-driving buffer circuit 32; and a second switch-driving buffer circuit 33.

The hysteresis comparator circuit 31 includes: resistors 311 to 314; and a hysteresis comparator 315 having an amount of hysteresis. The resistors 311 to 314 form a group of resistors that determines a voltage dividing ratio between a positive input (+) and a negative input (−) of the hysteresis comparator 315. The hysteresis comparator 315 compares a positive voltage that is a voltage applied to the positive input and a negative voltage that is a voltage applied to the negative input with each other, and switches the level of an output signal in accordance with a result of the comparison. Specifically, when detecting that the positive voltage has become higher than the negative voltage by a first value in a state where the level of the output signal is Low, the hysteresis comparator 315 switches the level of the output signal to a High level. When detecting that the positive voltage has become lower than the negative voltage by a second value in a state where the level of the output signal is High, the hysteresis comparator 315 switches the level of the output signal to a Low level. The first value and the second value may be the same or be different from each other.

In the circuit illustrated in FIG. 2, constants of the resistors 311 to 314 are set in such a manner that the positive voltage to the hysteresis comparator 315 becomes lower than the negative voltage thereto when a current flowing to the resistor 2, that is, a current flowing from the booster circuit 1 to the APD 7 is small, and a magnitude relation between the positive voltage and the negative voltage to the hysteresis comparator 315 is inverted when the current becomes large. Therefore, the hysteresis comparator 315 sets the output signal to a Low level in a state where the level of an optical signal input to the APD 7 is low and the current flowing to the resistor 2 is small. The hysteresis comparator 315 sets the output signal to a High level when the current flowing to the resistor 2 increases.

The first switch-driving buffer circuit 32 includes a buffer 321, resistors 322 and 324, and NPN transistors 323 and 325. The buffer 321 receives a signal output from the hysteresis comparator 315; performs waveform shaping and level conversion, for example; and outputs the resultant signal to the NPN transistors 323 and 325 at the subsequent stage. The buffer 321 outputs a High-level signal when the level of the received signal is High, where the level of this output signal is a level at which the NPN transistors 323 and 325 can be driven, that is, the level the NPN transistors 323 and 325 are turned on. The buffer 321 outputs a Low-level signal when the level of the received signal is Low, where the level of this output signal is a level at which the NPN transistors 323 and 325 cannot be driven, that is, the NPN transistors 323 and 325 are turned off. The resistors 322 and 324 drop the voltage of a line via which a voltage is applied from the booster circuit 1 to the APD 7.

The second switch-driving buffer circuit 33 includes a buffer 331, resistors 332 and 334, and NPN transistors 333 and 335. The buffer 331 receives a signal output from the hysteresis comparator 315, performs waveform shaping and level conversion, for example, and outputs the resultant signal to the NPN transistors 333 and 335 at the subsequent stage. The buffer 331 outputs a signal at a level at which the NPN transistors 333 and 335 cannot be driven when the level of the received signal is High, and outputs a signal at a level at which the NPN transistors 323 and 325 can be driven when the level of the received signal is Low. The signal output from the buffer 331 corresponds to an inversion of the signal output from the buffer 321 of the first switch-driving buffer circuit 32. The resistors 332 and 334 drop the voltage of a line via which a voltage is applied from the booster circuit 1 to the APD 7.

The switch circuit 4 includes CMOS (Complementary Metal Oxide Semiconductor) switches 4A and 4B connected in parallel to each other. The CMOS switch 4A that is a first switch includes an NMOS (N-Channel Metal Oxide Semiconductor) 41 and a PMOS (P-Channel Metal Oxide Semiconductor) 42. The CMOS switch 4A is turned on when abnormality occurs, specifically, when the level of an optical signal input to the APD 7 is a specified level or higher; and is turned off in normal times, that is, when the level of the optical signal input to the APD 7 is lower than the specified level. The specified level is a level at which a possibility of breakdown of the APD 7 is increased. The specified level may be determined based on a bit error rate that is deteriorated by an effect of a waveform distortion occurring in a case where the level of the optical signal input to the APD 7 is raised. For example, a level at which a bit error rate starts to be deteriorated by an effect of a waveform distortion is obtained by simulation or the like, and is used as the specified level. Alternatively, a level at which a bit error rate barely falls within a range required by a system may be obtained and be used as the specified level. The CMOS switch 4B that is a second switch includes an NMOS 43 and a PMOS 44. The CMOS switch 4B performs an opposite operation to the CMOS switch 4A, and is turned on in normal times and is turned off when abnormality occurs.

An operation of the burst light receiver 100 will be described next. An operation in a case where the level of an optical signal received by the burst light receiver 100 is normal, that is, an operation in a case where the level of an optical signal input to the APD 7 is lower than a specified level is described first.

In a case where a signal of which optical input power is within a range in which a normal operation is performed is input to the burst light receiver 100, the level of the optical signal input to the APD 7 is lower than the specified level. At this time, a current flowing to the resistor 2 is not equal to or larger than a predetermined threshold, and the level of an input signal to be input to a positive input terminal of the hysteresis comparator 315 is lower than the level of an input signal to be input to a negative input terminal. Therefore, the hysteresis comparator 315 outputs a Low-level signal. In association with this output, the buffer 321 in the first switch-driving buffer circuit 32 is set to a Low output, and the buffer 331 in the second switch-driving buffer circuit 33 is set to a High output. As a result: the NMOS 43 and the PMOS 44 of the CMOS switch 4B are turned on and a current from the booster circuit 1 flows through a path in which the CMOS switch 4B is inserted; however, the NMOS 41 and the PMOS 42 of the CMOS switch 4A are turned off and the current from the booster circuit 1 does not flow through a path in which the CMOS switch 4A and the high resistor 5 are inserted.

By applying: the configuration of the burst light receiver 100, specifically, a configuration in which a path including a high resistor for stepping down a voltage inserted therein, a path without the high resistor inserted therein, and a switch that switches these paths are provided, and the path without the high resistor is selected normally, to a burst light receiver; it is possible to achieve a high-speed burst response even if a capacitor corresponding to the decoupling capacitor 6 illustrated in FIG. 2 is inserted, as long as the value of a resistor corresponding to the resistor 2 illustrated in FIG. 2 is set to be small to some extent.

An operation in a case where the level of an optical signal received by the burst light receiver 100 is abnormal, that is, an operation in a case where the level of an optical signal input to the APD 7 is equal to or higher than the specified level will be described next.

In a case where a signal of which optical power is equal to or higher than an upper limit value of a range in which a normal operation is performed is input to the burst light receiver 100, the level of the optical signal input to the APD 7 is equal to or higher than the specified level. In this case, a current flowing to the resistor 2 becomes large, and the magnitude relation between input signals to the positive and negative input terminals of the hysteresis comparator 315 is inverted. When the level of the input signal to the positive input terminal of the hysteresis comparator 315 becomes higher than a value obtained by adding a first hysteresis to the level of the input signal to the negative input terminal, the hysteresis comparator 315 operates and outputs a High-level signal. In association with this output, the buffer 321 in the first switch-driving buffer circuit 32 is set to a High output, and the buffer 331 in the second switch-driving buffer circuit 33 is set to a Low output. As a result, the NMOS 43 and the PMOS 44 of the CMOS switch 4B through which a current has flowed previously are turned off, so that a current from the booster circuit 1 no longer flows. Meanwhile, the NMOS 41 and the PMOS 42 of the CMOS switch 4A are turned on, so that the current from the booster circuit 1 flows through a path in which the CMOS switch 4A is inserted. However, because the high resistor 5 is connected between the CMOS switch 4A and the APD 7, the amount of increase of the current flowing through this path is small and the voltage largely drops. The voltage applied to the APD 7 also drops. In association with this voltage drop, a current multiplication factor M is also lowered. Therefore, it is possible to avoid breakdown of the APD 7 caused by input of an optical signal of an excessively high level. In this example, by appropriately setting a resistance value of the high resistor 5, it is possible to raise the voltage on a cathode side of the APD 7 to be higher than the voltage on an anode side. Therefore, it is possible to avoid application of a reverse bias voltage to the APD 7 and is also possible to avoid breakdown of the APD 7 caused by application of the reverse bias voltage thereto.

When the hysteresis comparator 315 operates, the path of a current flowing from the booster circuit 1 to the APD 7 is switched. As a result, the amount of the current flowing to the resistor 2 is reduced, and the levels of input signals to the positive and negative input terminals of the hysteresis comparator 315 are also changed. The values of the resistors 311 to 314 are set in such a manner that the level of an output signal of the hysteresis comparator 315 is not switched from High to Low in association with this change of the current amount. Therefore, the hysteresis comparator 315 switches the level of an output signal therefrom from Low to High when a current flowing to the resistor 2 is changed from a state where the current is less than a first threshold to a state where the current is equal to or more than the first threshold; and the hysteresis comparator 315 switches the level of the output signal therefrom from High to Low when the current flowing to the resistor 2 is changed from a state where the current is equal to or more than a second threshold to a state where the current is less than the second threshold. Here, the second threshold is set to be smaller than the first threshold.

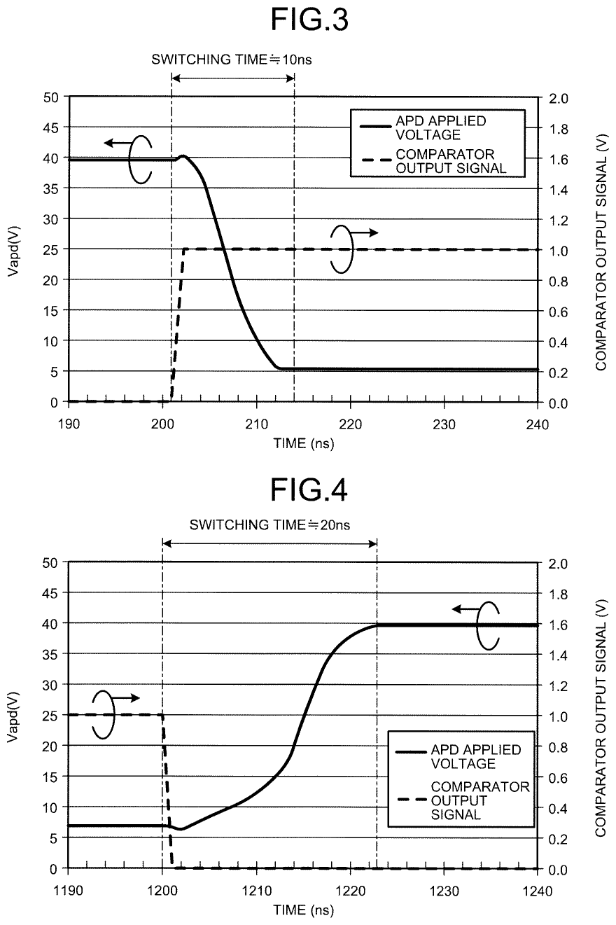

FIGS. 3 and 4 are diagrams illustrating an operation of the hysteresis comparator 315 according to the first embodiment illustrated in FIG. 2. FIG. 3 illustrates the level of a signal output from the hysteresis comparator 315 and a simulated waveform of change of the voltage applied to the APD 7 in a case where the level of an optical input to the APD 7 is changed from a normal level to an abnormal level, that is, a level equal to or higher than a specified level. FIG. 4 illustrates the level of the signal output from the hysteresis comparator 315 and a simulated waveform of change of the voltage applied to the APD 7 in a case where the level of the optical input to the APD 7 is changed from an abnormal level to the normal level. In FIGS. 3 and 4, a broken line represents a control signal that is the signal output from the hysteresis comparator 315, and a solid line represents an APD applied voltage (Vapd) that is the voltage applied to the APD 7.

In FIG. 3, during a normal operation in which the level of the optical input to the APD 7 is at a normal level, the APD applied voltage is about 40 volts and the output voltage of the hysteresis comparator 315 is 0 volt. After the hysteresis comparator 315 detects that the level of the optical input to the APD 7 has become abnormal, the output voltage of the hysteresis comparator 315 changes to 1.0 volt. As a result, the APD applied voltage drops to about 5 volts. From the simulation result, it is found that a time for this switching is about 10 nanoseconds. Therefore, it is found that, in a case of an excessive optical input, that is, a case where the level of the optical input to the APD 7 is abnormal, it is possible to drop the APD applied voltage instantaneously to protect the APD 7.

Meanwhile, in FIG. 4, during an abnormal operation in which the level of the optical input to the APD 7 is at an abnormal level, the APD applied voltage is about 7 volts and the output voltage of the hysteresis comparator 315 is 1.0 volt. After the hysteresis comparator 315 detects that the level of the optical input to the APD 7 has changed from the abnormal level to the normal level, the output voltage of the hysteresis comparator 315 changes to 0 volt. As a result, the APD applied voltage increases to about 40 volts that is the same as that in the normal operation. From the simulation result, it is found that a time for this switching is about 20 nanoseconds. Therefore, it is found that, after a state where the level of the optical input to the APD 7 is abnormal ends, it is possible to increase the APD applied voltage instantaneously, so that a burst signal can be received.

As described above, the light burst receiver according to the present embodiment includes: a first path and a second path that allow a current from a booster circuit that generates a voltage applied to an APD to the APD to flow therethrough; a switch circuit that selects the first path or the second path; and a current detecting circuit that controls the switch circuit based on a value of the current flowing from the booster circuit to the APD. A high resistor for stepping down the voltage applied to the APD is inserted in the first path. The current detecting circuit controls the switch circuit to select the first path when the current flowing from the booster circuit to the APD becomes equal to or larger than a first threshold, and to select the second path when the current flowing from the booster circuit to the APD becomes smaller than a second threshold. That is, the current detecting circuit controls the switch circuit in such a manner that the current flowing from the booster circuit to the APD: passes through the second path when the level of an optical input to the APD is a normal level; and passes through the first path when the level of the optical input to the APD is an abnormal level. With this configuration, the current flows to the APD via the second path in which the high resistor is not inserted, when the level of the optical input to the APD is the normal level. Therefore, sensitivity can be improved, and it is possible to prevent a time required for detecting change of the level of the optical input to the APD in a case where that level is changed to the abnormal level, from becoming long even in a configuration including a decoupling capacitor. Meanwhile, in a case where the level of the optical input to the APD is the abnormal level, the current flows to the APD via the first path in which the high resistor is inserted, and a voltage that is stepped down by the high resistor is applied to the APD. Therefore, the APD can be protected. As described above, according to the light burst receiver of the present embodiment, it is possible to shorten a required time from input of an optical signal at an abnormal level to the APD until the voltage applied to the APD is stepped down to lower the current multiplication factor. It is also possible to cause the value of resistance for stepping down the voltage applied to the APD to be sufficiently large. Therefore, performance of protecting the APD can be improved.

### Second Embodiment

In the first embodiment described above, a burst light receiver configured to use the hysteresis comparator circuit 31 with respect to a preset fixed threshold has been described. On the other hand, in a second embodiment, a burst light receiver is described in which an operating point of a hysteresis comparator can be changed considering individual variation and temperature-dependent characteristics of an APD, for example.

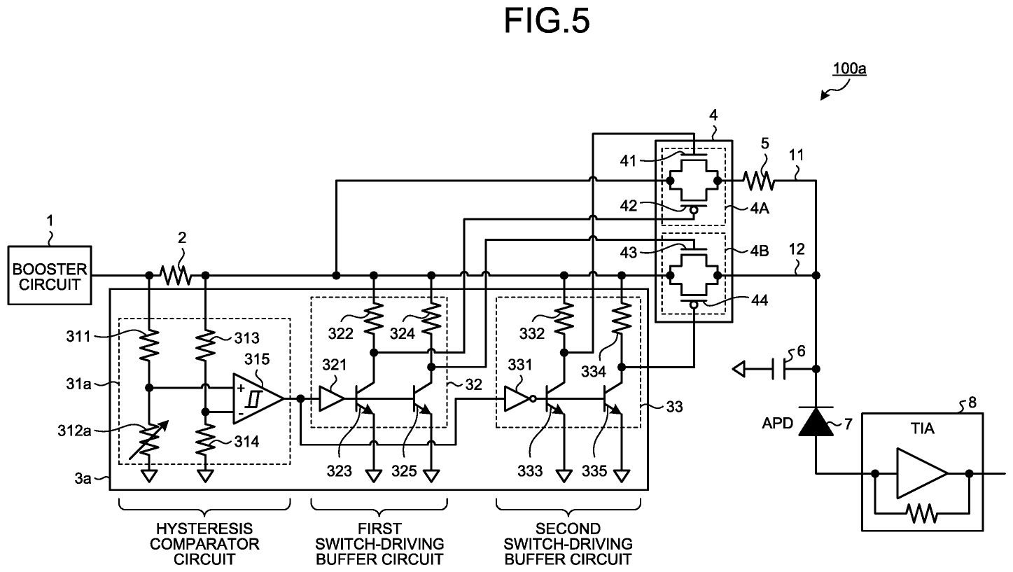

FIG. 5 is a diagram illustrating a configuration example of a burst light receiver according to the second embodiment. A burst light receiver 100a according to the second embodiment corresponds to the burst light receiver 100 according to the first embodiment in which the hysteresis comparator circuit 31 is replaced with a hysteresis comparator circuit 31a. The hysteresis comparator circuit 31a has a configuration obtained by replacing the resistor 312 of the hysteresis comparator circuit 31 according to the first embodiment with a variable resistor 312a. Constituent elements of the burst light receiver 100a, other than the variable resistor 312a, are identical to those of the burst light receiver 100.

By replacing the resistor 312 with the variable resistor 312a, it is possible to adjust an input voltage value on a positive (+) side of the comparator 315 having an amount of hysteresis. Therefore, it is possible to compensate the variation amount of a threshold for path switching by the switch circuit 4 caused by individual variation and temperature dependence of the APD 7, and it is possible to switch a path through which a current flows from the booster circuit 1 to the APD 7, at a timing that is appropriate for variation of the level of an optical input to the APD 7.

The configurations described in the above embodiments are only examples of the content of the present invention. The configurations can be combined with other well-known techniques, and a part of each configuration can be omitted or modified without departing from the scope of the present invention.

### REFERENCE SIGNS LIST

1 booster circuit, 2, 311, 312, 313, 314, 322, 324, 332, 334 resistor, 3 current detecting circuit, 4 switch circuit, 4A, 4B CMOS switch, 5 high resistor, 6 decoupling capacitor, 7 avalanche photodiode (APD), 8 transimpedance amplifier, 11 first path, 12 second path, 31, 31a hysteresis comparator circuit, 32 first switch-driving buffer circuit, 33 second switch-driving buffer circuit, 41, 43 NMOS, 42, 44 PMOS, 321, 331 buffer, 323, 325, 333, 335 NPN transistor.

1. A burst light receiver comprising:
a booster circuit to generate a voltage applied to an avalanche photodiode;
a first path provided between the booster circuit and the avalanche photodiode, in which a resistor to step down the voltage generated by the booster circuit is inserted;
a second path provided in parallel to the first path;
a switch circuit provided between the booster circuit and the first and second paths, to connect the booster circuit to the first path or the second path; and
a path selecting unit to control the switch circuit in such a manner that the booster circuit is connected to the first path when a value of a current flowing from the booster circuit to the avalanche photodiode becomes equal to or larger than a first threshold, and the booster circuit is connected to the second path when the value of the current becomes smaller than a second threshold.

2. The burst light receiver according to claim 1, wherein no circuit element to step down the voltage generated by the booster circuit is included in the second path.

3. The burst light receiver according to claim 1, wherein the first threshold is larger than the second threshold.

4. The burst light receiver according to claim 1, further comprising a decoupling capacitor provided between the first and second paths and the avalanche photodiode.

5. The burst light receiver according to claim 1, wherein the path selecting unit includes a hysteresis comparator to start to output a High-level signal when the value of the current is changed from a state where the value is smaller than the first threshold to a state where the value is equal to or larger than the first threshold, and to start to output a Low-level signal when the value of the current is changed from a state where the value is equal to or larger than the second threshold to a state where the value is smaller than the second threshold.

6. The burst light receiver according to claim 5, further comprising a current detecting resistor to detect the value of the current, wherein
a voltage of a terminal of the current detecting resistor on a side of the booster circuit is divided and applied to a positive input terminal of the hysteresis comparator, and a voltage of a terminal of the current detecting resistor on a side of the avalanche photodiode is divided and applied to a negative input terminal of the hysteresis comparator, and
a voltage dividing ratio of the voltage applied to the positive input terminal is variable.

7. The burst light receiver according to claim 5, wherein
the switch circuit includes a first switch and a second switch connected in parallel to each other, the first switch and the second switch being formed of an n-channel metal oxide semiconductor and a p-channel metal oxide semiconductor, respectively,
the first path is connected to the first switch,
the second path is connected to the second switch, and
the path selecting circuit includes
a first switch-driving buffer circuit to turn off the first switch when the hysteresis comparator outputs a Low-level signal, and to turn on the first switch when the hysteresis comparator outputs a High-level signal, and
a second switch-driving buffer circuit to turn on the second switch when the hysteresis comparator outputs a Low-level signal, and to turn off the second switch when the hysteresis comparator outputs a High-level signal.
